(19) United States
(12) Patent Application Publication
(10) Pub. No.: US 2008/0173241 A1
(43) Pub. Date: Jul. 24, 2008

(54) Vapor deposition sources and methods

(76) Inventors: Scott Wayne Priddy, Saint Louis Park, MN (US); Richard Charles Bresnahan, Cottage Grove, MN (US); Chad Michael Conroy, Stillwater, MN (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 12/002,526

(22) Filed: Dec. 17, 2007

Related U.S. Application Data
(60) Provisional application No. 60/875,651, filed on Dec. 19, 2006.

(51) Int. Cl. C23C 16/455; B01D 7/00

(52) U.S. Cl. 118/726; 392/389

(57) ABSTRACT

Vapor depositions sources, systems, and related deposition methods. Vapor deposition sources for use with materials that evaporate or sublime in a difficult to control or otherwise unstable manner are provided. The present invention is particularly applicable to deposition of organic material such as those for forming one or more layer in organic light emitting devices.

### CROSS-REFERENCE TO RELATED APPLICATION

The present application claims priority to U.S. Provisional Application No. 60/875,651, filed Dec. 19, 2006, the entire contents of which is incorporated herein by reference for all purposes.

### TECHNICAL FIELD

The present invention relates to vapor depositions sources, systems, and related deposition methods. More particularly, the present invention relates to vapor deposition sources for use with materials that evaporate or sublime in a difficult to control or otherwise unstable manner. For example, the present invention is particularly applicable for depositing organic materials such as those for use in an organic light-emitting device (OLED).

### BACKGROUND

An organic light-emitting device, also referred to as an organic electroluminescent device, is typically constructed by sandwiching two or more organic layers between first and second electrodes. In a passive matrix organic light-emitting device of conventional construction, a plurality of laterally spaced light-transmissive anodes, for example indium-tin-oxide anodes, are formed as first electrodes on a light-transmissive substrate such as, for example, a glass substrate. Two or more organic layers are then formed successively by vapor deposition of respective organic materials from respective sources, within a chamber held at reduced pressure, typically less than a millitorr. A plurality of laterally spaced cathodes is deposited as second electrodes over an uppermost one of the organic layers. The cathodes are oriented at an angle, typically at a right angle, with respect to the anodes.

Applying an electrical potential (also referred to as a drive voltage) operates such conventional passive matrix organic light-emitting devices between appropriate columns (anodes) and, sequentially, each row (cathode). When a cathode is biased negatively with respect to an anode, light is emitted from a pixel defined by an overlap area of the cathode and the anode, and emitted light reaches an observer through the anode and the substrate.

In an active matrix organic light-emitting device, an array of anodes are provided as first electrodes by thin-film transistors, which are connected to a respective light-transmissive portion. Two or more organic layers are formed successively by vapor deposition in a manner substantially equivalent to the construction of the passive matrix device described above. A common cathode is deposited as a second electrode over an uppermost one of the organic layers. The construction and function of an exemplary active matrix organic light-emitting device is described in U.S. Pat. No. 5,550,066, the entire disclosure of which is incorporated by reference herein for all purposes.

Organic materials, thicknesses of vapor-deposited organic layers, and layer configurations, useful in constructing an organic light-emitting device, are described, for example, in U.S. Pat. Nos. 4,356,429, 4,539,507, 4,720,432, and 4,769,292, the entire disclosures of which are incorporated by reference herein for all purposes.

An exemplary organic material used in OLED's is Alq3 (Aluminum Tris (8-Hydroxyquinoline)). This material and others like it are typically characterized as having poor thermal conductivity, which makes it difficult to uniformly heat the material to vaporize it. Moreover, these organic materials are typically provided in powder or granular form, which also makes it difficult to uniformly heat the material. Such nonuniformity in heating the material causes nonuniform vaporization of the material (by sublimation). Such nonuniform vapor flux, directed at a substrate or structure, will cause the formation of an organic layer thereon which will have a nonuniform layer thickness in correspondence with the nonuniform vapor flux.

A source for thermal physical vapor deposition of organic layers onto a structure for making an organic light-emitting device is described in U.S. Pat. No. 6,237,529 to Spahn. Another source for deposing organic layers is described in U.S. Pat. No. 6,837,939 to Klug et al. The Spahn and Klug et al. sources for depositing organic layers are representative of the current state of the art. These sources attempt to address the nonuniformity experienced in depositing these materials by using solid or bulk material instead of the granular form of the material. The Spahn source uses an arrangement of baffles and apertured plates to help minimize particulates that can be ejected by the source material but does not address the above-noted uniformity issue. The Klug et al. source uses a mechanism that advances compacted pellets of deposition material into a heated zone and an arrangement of baffles and apertured plates to address the uniformity problem. However the Klug et al. source is complex and cannot regulate and/or meter the vaporized material.

### SUMMARY

The present invention thus provides vapor deposition sources and deposition methods that provide stable and controllable flux of materials that evaporate or sublime nonuniformly or in an unstable manner. Such materials are typically characterized as having one or more of low or poor thermal conductivity, a granular, flake, or powder consistency, and one or more inorganic components. Moreover, such materials typically sublime from a solid state rather that evaporate from a liquid (molten) state and do so in an unstable or difficult to regulate manner. Materials that sublime are also sensitive to thermal treatment as they may sublime as desired yet decompose undesireably within a narrow range of temperatures.

Deposition sources and methods in accordance with the present invention thus provide the ability to controllably heat a deposition material in a manner that optimizes evaporation or sublimation and minimizes nonuniform heating, heating of undesired portions of a deposition material within a crucible, and undesired decomposition of a deposition material when heated to evaporate or sublime the material.

Deposition sources and methods of the present invention are particularly applicable to depositing organic materials for forming one or more layers in organic light emitting devices.

Accordingly, in an aspect of the present invention, a vacuum deposition source is provided. The vacuum deposition source comprises a body attachable to a vacuum deposition system, the body comprising first and second body portions separable from each other; a valve positioned at least partially in the first body portion, the valve having an input side and an output side; a crucible at least partially positioned in the second body portion and in communication with the input side of the valve, the crucible comprising a plurality of distinct deposition material cells; and a nozzle comprising at least one exit orifice, the nozzle at least partially positioned in the first body portion and in communication with the output side of the valve.

In another aspect of the present invention, a vacuum deposition source is provided. The vacuum deposition source comprises a body attachable to a vacuum deposition system, the body comprising first and second body portions separable from each other; a valve positioned at least partially in the first body portion, the valve having an input side and an output side; a crucible at least partially positioned in the second body portion, detachably sealed to the input side of the valve, and isolated from the second body portion, the crucible comprising at least one deposition material cell; and a nozzle comprising at least one exit orifice, the nozzle at least partially positioned in the first body portion and in communication with the output side of the valve.

In another aspect of the present invention, a vacuum deposition system is provided. The vacuum deposition system comprises a vacuum chamber; a vacuum deposition source attached to the vacuum chamber, the vacuum deposition source comprising first and second body portions separable from each other, a valve positioned at least partially in the first body portion, the valve having an input side and an output side, a crucible at least partially positioned in the second body portion and in communication with the input side of the valve, the crucible comprising a plurality of distinct deposition material cells, and a nozzle comprising at least one exit orifice, the nozzle at least partially positioned in the first body portion and in communication with the output side of the valve; a deposition material provided in one or more of the plurality of deposition material cells of the crucible; and a substrate positioned in the vacuum chamber and relative to the nozzle of the vacuum deposition source.

In another aspect of the present invention, a crucible for a deposition source is provided. The crucible comprises a body portion; a flange comprising a knife-edge capable of providing a seal with a gasket when the flange is attached to a similar flange; and a plurality of distinct cells for holding deposition material.

In another aspect of the present invention, a method of vaporizing material for vacuum deposition is provided. The method comprises the steps of providing a crucible comprising a plurality of distinct deposition material cells; positioning deposition material in at least one of the plurality of deposition material cells of the crucible; and heating the crucible to vaporize the deposition material.

In another aspect of the present invention, a method of vaporizing material for vacuum deposition is provided. The method comprises the steps of providing a crucible comprising at least one deposition material cell at least partially defined by a plural rods; positioning deposition material in at least one deposition material cell of the crucible; and heating the crucible to vaporize the deposition material.

### BRIEF DESCRIPTION OF THE DRAWINGS

These and other features, aspects, and advantages of the present invention will become better understood with regard to the following description, appended claims, and accompanying drawings where:

FIG. 1 is a perspective view of an exemplary vapor deposition source in accordance with the present invention;

FIG. 2 is a schematic cross-sectional view of an exemplary vapor deposition source in accordance with the present invention showing in particular a crucible having plural distinct cells for holding deposition material;

FIG. 3 is a schematic perspective partial cross-sectional view of the deposition source of FIG. 1 taken along a different cross-sectional line than that of FIG. 2;

FIG. 4 is a schematic cross-sectional view of a vapor deposition source similar to the source shown in FIG. 1 and having a different exemplary nozzle;

FIG. 5 is a perspective view of the crucible of the deposition source of FIGS. 1-3;

FIG. 6 is a perspective view of another exemplary crucible in accordance with the present invention showing, in particular, plural deposition material cells of concentric channels;

FIG. 7 is a top view of the crucible of FIG. 6;

FIG. 8 is a cross-sectional view of the crucible of FIG. 6;

FIG. 9 is a top view of another exemplary crucible in accordance with the present invention showing, in particular, plural deposition material cells of parallel channels;

FIG. 10 is a cross-sectional view of the crucible of FIG. 9;

FIG. 11 is cross-sectional perspective view of another exemplary crucible in accordance with the present invention showing, in particular, an array of rods that define, together with the wall of the crucible, a single deposition material cell;

FIG. 12 is a perspective view of another exemplary crucible in accordance with the present invention showing, in particular, an array of distinct material deposition cells supported by a plate at an opening of the cells;

FIG. 13 is a cross-sectional view of the crucible of FIG. 12;

FIG. 14 is a schematic cross-sectional view of another exemplary crucible in accordance with the present invention showing, in particular, an array of distinct material deposition cells supported by a plate at a base of the cells;

FIG. 15 is a perspective view of another exemplary crucible in accordance with the present invention showing, in particular, a single deposition material cell;

FIG. 16 is another exemplary deposition source in accordance with the present invention showing, in particular, an alternate valve orientation;

FIG. 17 is cross-sectional perspective view of another exemplary crucible in accordance with the present invention showing, in particular, an array of rods that define, together with the wall of the crucible, a single deposition material cell and plural heaters integrated with the rods;

FIG. 18 is a schematic cross-sectional view of a vapor deposition source similar to the source shown in FIG. 1 and having a different exemplary nozzle wherein the nozzle comprises a heating device;

FIG. 19 is a perspective view of a vapor deposition source similar to the source shown in FIG. 1 and having a different exemplary nozzle.

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

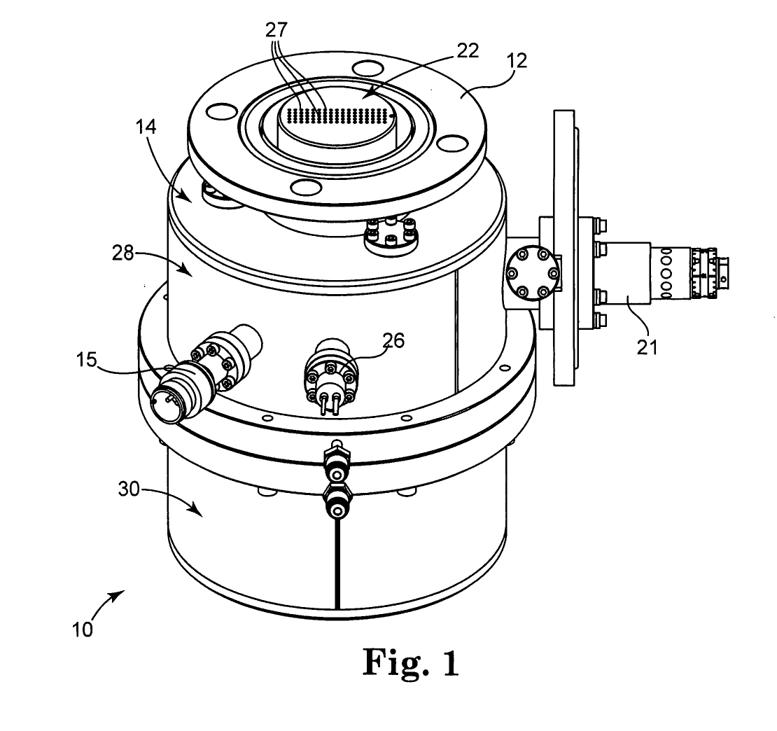

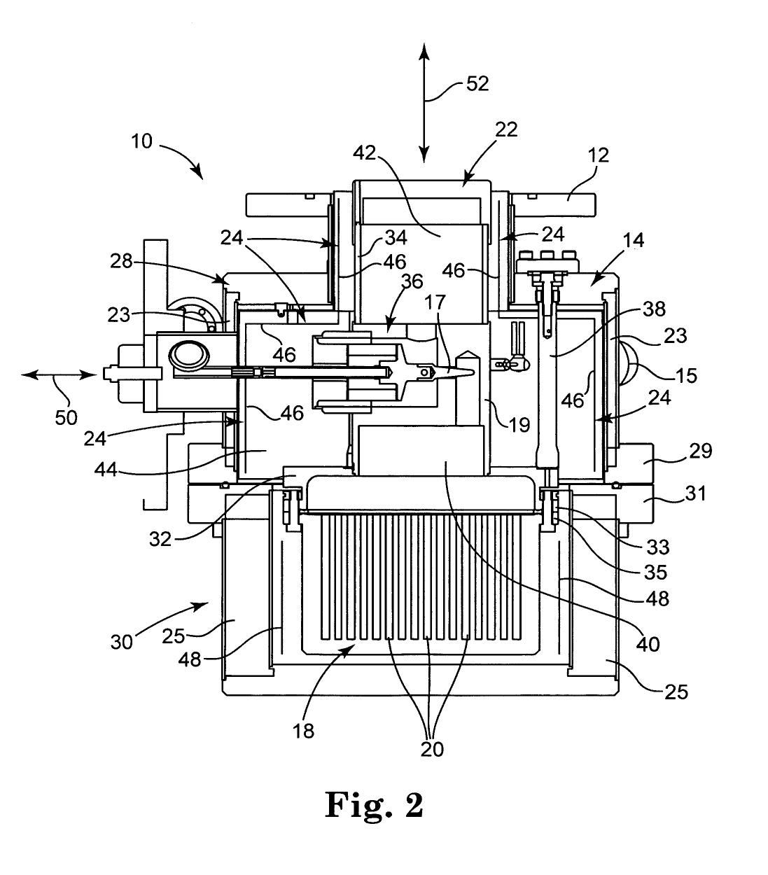

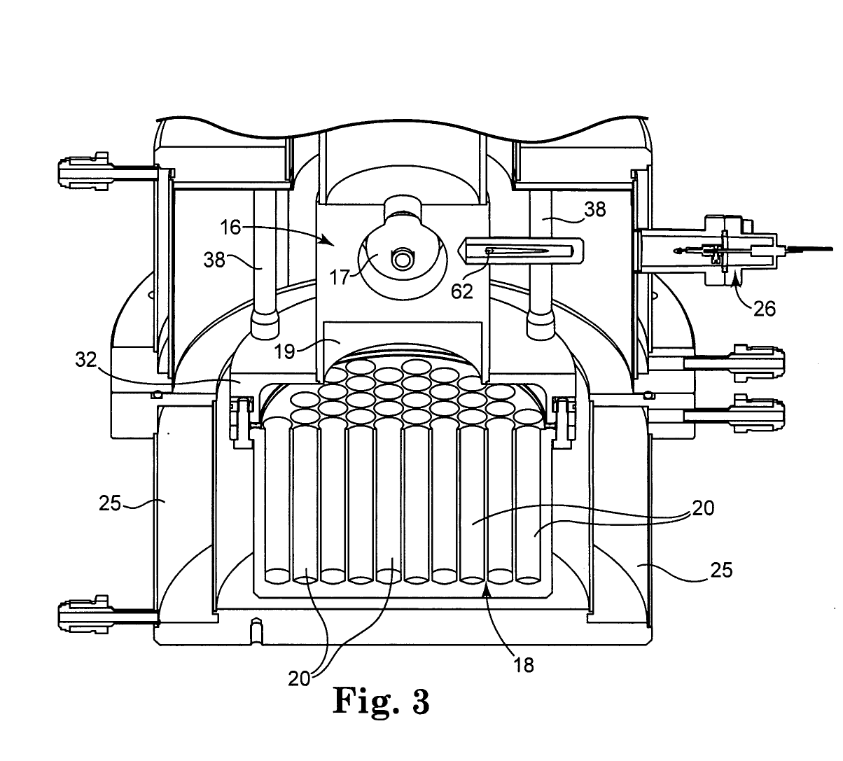

Referring initially to FIGS. 1-3 an exemplary vapor deposition source 10 in accordance with the present invention is illustrated. In FIG. 1 a perspective view of deposition source 10 is shown. In FIG. 2 a schematic cross-sectional view of deposition source 10 is shown. FIG. 3 shows a partial schematic cross-sectional perspective view along a different cross section line than that of FIG. 2.

The exemplary deposition source 10 illustrated in FIGS. 1-3 is designed for vacuum deposition and, as illustrated, generally includes mounting flange 12 for attaching deposition source 10 to a deposition system (not shown), body 14 attached to flange 12, valve 16, crucible 18 comprising plural cells 20, nozzle 22, and heater assembly 24 for providing heat, preferably radiant, to evaporate or sublime material located in crucible 18 and prevent deposition of such material on undesired surfaces (valve 16 and nozzle 22, for example). Valve 16 comprises valve portion 17 and valve body 19. Deposition source 10, as shown, also preferably comprises water jackets 23 and 25 for cooling, power feedthrough 15 for providing power to heater assembly 24, and feedthrough 26 for a thermocouple, or similar sensor. Although crucible 18 is illustrated with plural cells, a crucible having a single cell can be used.

Body 14 of exemplary deposition source 10, as shown, comprises first body portion 28 attached to mounting flange 12 and second body portion 30 attached to first body portion 28. Body 14 preferably comprises stainless steel as is well known for vacuum deposition components. Body 14 is preferably designed so crucible 18 can be accessed and/or removed for maintenance, replacement, and so deposition material can be added/removed as needed. In particular, first body portion 28 includes flange 29 removably connected to flange 31 of second body portion 30. In the illustrated embodiment, second body portion 30 is separable from first body portion 28 to access crucible 18. Crucible 18, as shown, is separably attached to plate 32 by flange 33 of plate 32 and flange 35 of crucible 18. The connection between crucible 18 and plate 32 is preferably vacuum tight and resealable. For example, a Conflate style seal can be used which seal comprises flanges having knife-edges that embed into a soft metal seal gasket such as a copper or niobium gasket or the like. Alternatively, a graphite seal material can be used such as a flexible graphite gasket material positioned between polished flange surfaces. Such graphite material is available from GrafTech Advanced Energy Technology, Inc. of Lakewood, Ohio. Plate 32, as shown, is welded to valve body 19 to provide a vacuum tight enclosure between crucible 18 and valve 16. In the illustrated design, second body portion 30 can be separated from first body portion 28 to access crucible 18 and crucible 18 can be separated from plate 32 to replace crucible 18, add/remove source material, for example.

Plate 32, as shown, is attached to valve body 19, which is attached to nozzle 22, via tube 34 as shown. Plate 32, valve body 19, and tube 34 are preferably welded to each other but other connection techniques can be used for permanent connection of one or more of the components of assembly 36 (brazing, for example) or resealable connections (using gaskets, for example). Crucible 18, plate 32, valve body 19, and tube 34 preferably comprise vacuum compatible materials such as titanium and stainless steel and the like. Preferably, as illustrated, assembly 36 comprising crucible 18, plate 32, valve body 19, tube 34, and nozzle 22 is thermally isolated from body 14 of deposition source 10. In the illustrated design, such isolation is accomplished by supporting or hanging assembly 36 from first body portion 28. Preferably, support legs 38 connected to first body portion 28 and connected to plate 32, as shown, are used.

Preferably, as illustrated, crucible 18, plate 32, valve body 19, and valve portion 17 define first vacuum zone 40 distinct from second vacuum zone 42 defined by the valve body 19, valve portion 17, tube 34, and nozzle 22. Communication between first and second vacuum zones, 40 and 42, respectively, is controlled by valve 16. A third distinct vacuum zone 44 is defined by the space between first and second body portions 28 and 30, respectively, and crucible 18, plate 32, valve body 19, tube 34, and nozzle 22. Third vacuum zone 44 is in communication with a vacuum chamber (not shown) when the deposition source 10 is attached to such vacuum chamber. In use, third vacuum zone 44 is preferably maintained at a vacuum level that minimizes convective heat transfer between first and second body portions 28 and 30, respectively, and crucible 18, plate 32, valve body 19, tube 34, and nozzle 22. For example, maintaining third vacuum zone 44 below about 50 millitorr helps to minimize such convective heat transfer.

Deposition source 10 includes heater assembly 24 for providing thermal energy that functions to evaporate or sublime material located in crucible 18. Crucible 18 or a desired portion(s) thereof can be heated radiatively (indirectly) or can be heated directly such as by resistively or conductively heating crucible 18 or a desired portion(s) of crucible 18. Combinations of indirect, direct, radiative, resistive, conductive heating, and the like can be used. In the illustrated embodiment, heater portion 46 is schematically shown positioned in first body portion 28. Plural distinct heaters can be used. Preferably such a heater comprises one or more filaments that are resistively heated to provide radiant thermal energy. Here, heater portion 46 radiatively heats nozzle 22, tube 34, valve 16, and plate 32. Such heating may be direct, indirect, or combinations thereof. One or more heaters can be used that are spaced from and/or in contact with component(s) desired to be heated. Heating such components functions to prevent deposition of material onto such components especially valve body 19 and valve portion 17, which could cause unwanted build up of material. Crucible 18 is partly heated by conduction between valve 16, plate 32 and crucible 18 as well as radiation from plate 32 and valve body 19. In this design, the deposition material in each cell 20 of crucible 18 is primarily heated from above as the conductive heating between plate 32 and crucible 18 is minimal. That is, radiative heat from plate 32 and valve body 19 is the primary source of heating for crucible 18 and particularly for deposition material provided in crucible 18.

Second body portion 30 can include one or more optional heater(s) 48 for heating crucible 18, directly or indirectly. Such heater can be spaced from and/or in contact with crucible 18. Preferably, heater portion 48 for second body portion 30 is distinct from heater portion 46 in first body portion 28 so heater portion 46 and heater portion 48 can be operated independently from each other. Whether or not second body portion 30 includes one or more heaters to heat crucible 18 depends on factors such as the particular deposition material, desired flux uniformity, desired flux rate, crucible design, deposition source geometry, and combinations thereof, for example. Deposition source 10 can be designed to include plural heaters (of the same of different types) in any of first and second body portions 28 and 30, respectively, or within any of the vacuum zones. Thus, depending on the particular deposition material, any single or combination of heaters can be used. Determining what portion(s) of deposition source 10 is heated, not heated, or cooled, and how, is generally at least partially dependent on the characteristics of the particular deposition material used and can be determined empirically to obtain desired performance objective(s) such as one or more of deposition uniformity, flux rate, flux stability, material usage efficiency, and minimizing coating of valve components for example.

Valve 16 is designed for vacuum use and can preferably withstand being heated during use of deposition source 10. Valve 16 preferably includes a driver or actuator 21 (see FIG. 3) to provide computer (signal-based) control of valve 16. An exemplary actuator is Part No. SMC-II, available from Veeco Compound Semiconductor Inc. of St. Paul, Minn. Depending on the deposition material and/or deposition process valve 16 can provide regulating, metering, on/off functionality, combinations thereof, for example. Preferably, valve 16 is capable of creating a pressure differential between first and second vacuum zones, 40 and 42, respectively, such as for providing a backpressure in first vacuum zone 40. As shown, valve portion 17 moves along an axis (identified by reference numeral 50) different from the axis of material evaporation and/or sublimation from crucible 18 (identified by reference numeral 52). In an alternative design, valve portion 17 can move along the axis of material evaporation as shown schematically in FIG. 10 and described below. Effusion cells having valves for use in the context of vapor deposition are described in U.S. Pat. No. 6,030,458 to Colombo et al., for example, the entire disclosure of which is incorporated by reference herein for its entire technical disclosure including, but not limited to, the disclosure of such valves and for all purposes.

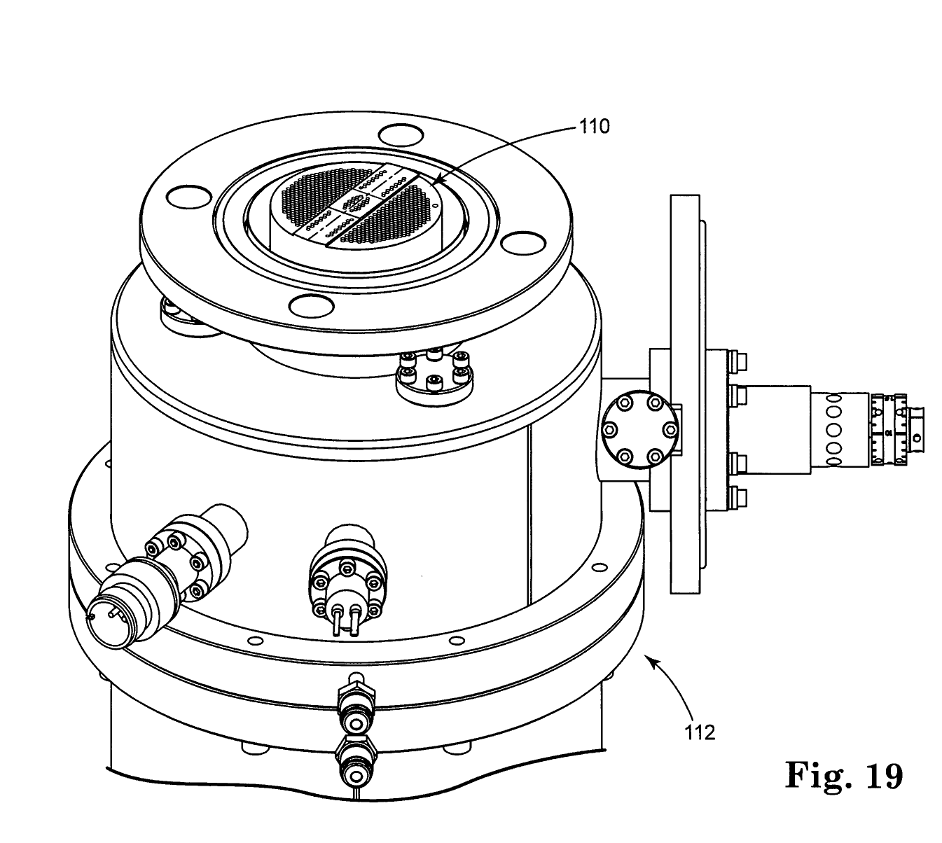

Deposition source 10, as shown, includes nozzle 22. Nozzle 22 is preferably designed to provide desired deposition performance. Typically, nozzle 22 includes one or more openings (orifices) for emitting and/or directing deposition material in a predetermined direction and/or rate. Nozzle orifices are preferably arrayed to provide optimal uniformity across a wide substrate. Typically there is a uniform set of orifices across the nozzle with a higher concentration near the ends of the nozzle to compensate for the flux roll off at the end of the nozzle. As illustrated, nozzle 22 comprises plural exit orifices 27 but a single exit orifice may be used. Factors used in designing the nozzle include deposition material, deposition uniformity, deposition rate, deposition system geometry, and the number, type, and size of substrates deposited on. Such nozzles can be designed using empirical data, information, and/or techniques. Another exemplary nozzle 110 is shown with deposition source 112 in FIG. 19. Nozzles that can be used with deposition sources in accordance with the present invention are available from Veeco Compound Semiconductor Inc. of St. Paul, Minn.

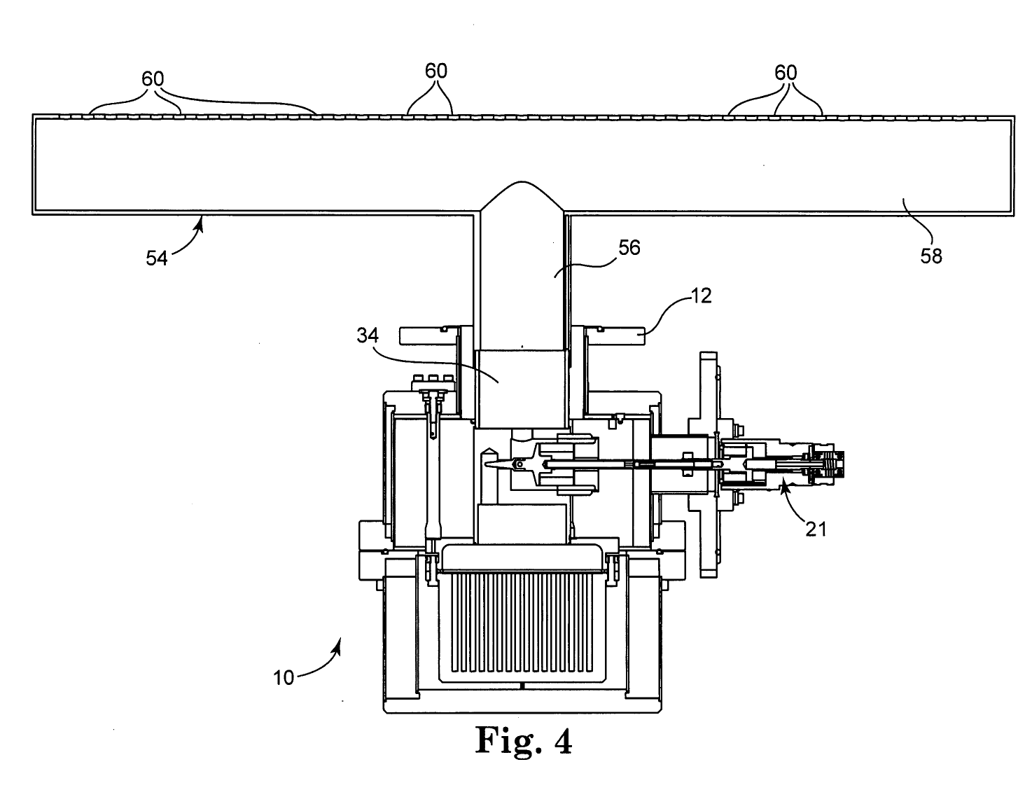

An alternative nozzle 54 is illustrated in FIG. 4 and is designed to provide increased areal coverage by the emitted vapor deposition flux. As shown, nozzle 54 comprises tube 56 and body portion 58 having plural exit apertures 60. Tube 56 functions to space body portion 58 from flange 12 of deposition source 10. Such spacing is dependent on the particular deposition application for which deposition source 10 is used. As shown, body portion 58 extends linearly and orthogonally relative to tube 56. Body portion 58 may be provided at any desired angle relative to tube 56. As shown, body portion 58 comprises a tube (cylinder) but may comprise a planar structure such as a cube, rectangle, or disk or may comprise an arcuate structure such as a sphere or similar arcuate surface or the like. Body portion 58 may comprise any number of exit apertures (including a single exit aperture). Such exit apertures may comprise any shape (e.g., circular, elliptical, square, rectangular) or combinations of such shapes. Nozzle 54 does not need to be symmetric and the density of such exit apertures may vary between regions of nozzle 54. A nozzle is not required for some applications and a single orifice may be sufficient. That is, tube 34 also functions as a nozzle in the absence of nozzle 22 and nozzle 54.

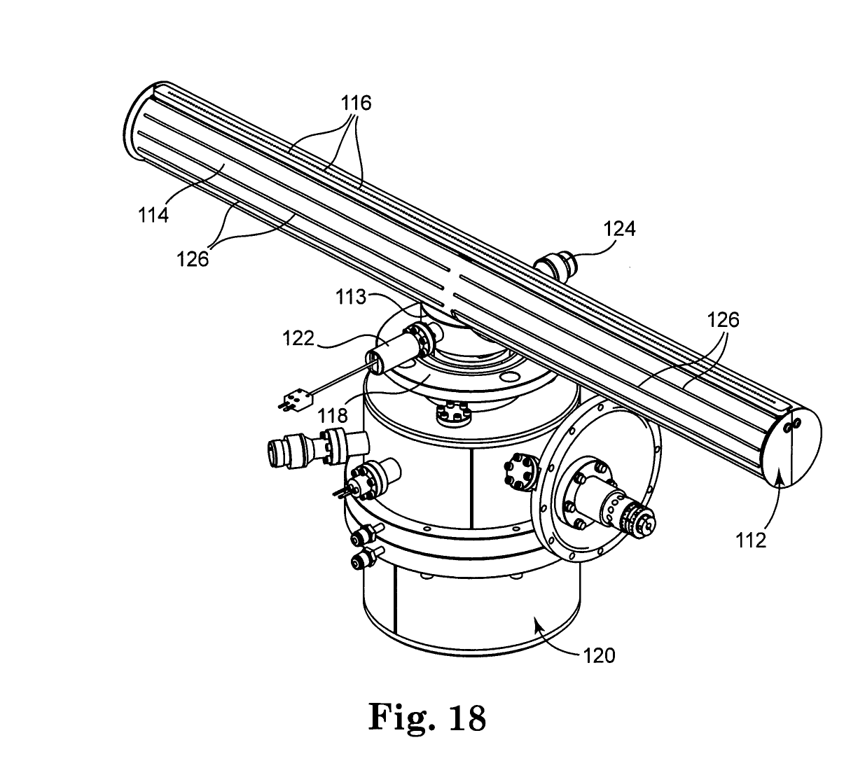

An alternative nozzle 112 is illustrated in FIG. 18. As shown, nozzle 112 comprises tube 113 and body portion 114 having plural exit apertures 116. Tube 113 functions to space body portion 114 from flange 118 of deposition source 120. Tube 113 also functions to house thermocouple feedthrough 122 and power feedthrough 124 for nozzle 112. Nozzle 112 also comprises heating elements 126 connected to power feedthrough 124 the temperature of which can be controlled by feedback from thermocouple feedthrough 122. Plural heating elements are shown but a single element may be used. Heating elements 126 are shown on an exterior surface of nozzle 112 but may be provided inside nozzle 112. As shown, body portion 114 extends linearly and orthogonally relative to tube 113. Body portion 114 may be provided at any desired angle relative to tube 113. As shown, body portion 114 comprises a tube (cylinder) but may comprise a planar structure such as a cube, rectangle, or disk or may comprise an arcuate structure such as a sphere or similar arcuate surface or the like. Body portion 114 may comprise any number of exit apertures (including a single exit aperture). Such exit apertures may comprise any shape (e.g., circular, elliptical, square, rectangular) or combinations of such shapes. Nozzle 112 does not need to be symmetric and the density of such exit apertures may vary between regions of nozzle 112.

Deposition source 10 also preferably includes other components and/or design aspects as needed depending on the particular deposition material and/or deposition process. For example, the illustrated deposition source 10 includes a thermocouple 62 for temperature measurement and is used for controlling deposition flux. Thermocouple 62 is preferably designed to be in contact with valve body 19. Type-K and Type-J thermocouples can be used. Plural thermocouples or temperature sensors or control systems can be used. The illustrated deposition source 10 also incorporates liquid cooling jacket 25, preferably water, for managing and/or cooling desired portions of deposition source 10.

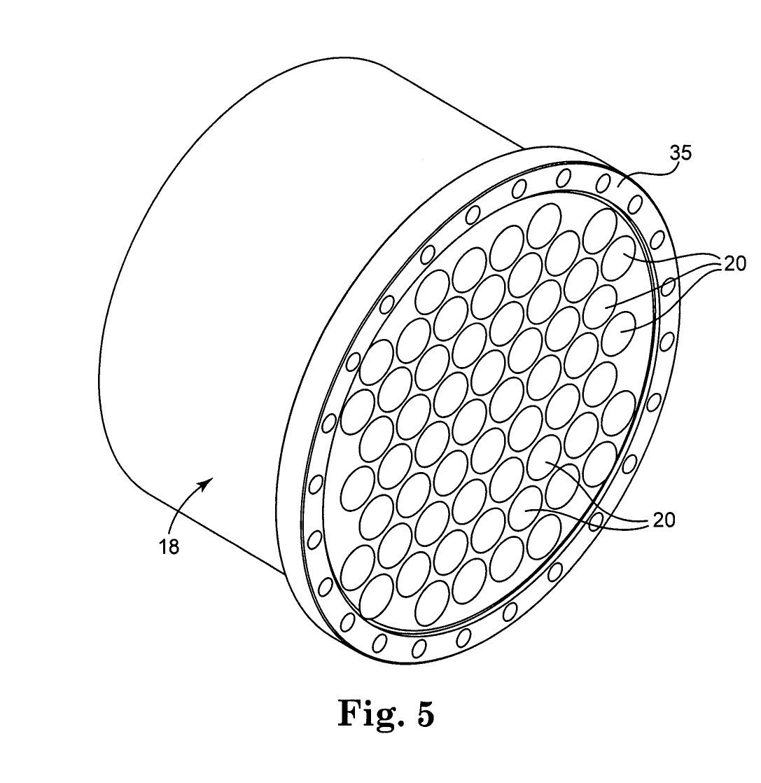

As shown, crucible 18 is designed to provide plural distinct cells or chambers for holding deposition material but a single cell can also be used. Exemplary crucibles that provide plural distinct cells are shown in FIGS. 5-15.

FIG. 5 shows a perspective view of exemplary crucible 18, as shown, crucible 18 is designed to contain about 500 cubic centimeters of deposition material as measured by adding the volume of all cells 20 but any volume can be used depending on the application. Depending on the application, crucible 18 can be made from a thermally conductive material or thermally insulative material. Representative materials include metals, ceramics, glasses, and composites, for example. Specific examples include titanium, stainless steel, copper, aluminum, graphite, silicon carbide, nickel based alloys, and alumina. Cells 20 can have any cross-sectional shape, volume, aspect ratio, number, and/or arrangement depending on the particular application and/or deposition material and depending on the particular functionality desired. For example, cells 20 can be designed to provide uniform heating of material in cells 20 or can alternatively be designed to insulate cells 20 from each other. Crucibles in accordance with the present invention may include heating devices integrated with such crucibles. For example, a heating device may be provided on an external surface of a crucible. Alternatively, a heating device may be in or adjacent to one or more cells of a crucible in accordance with the present invention.

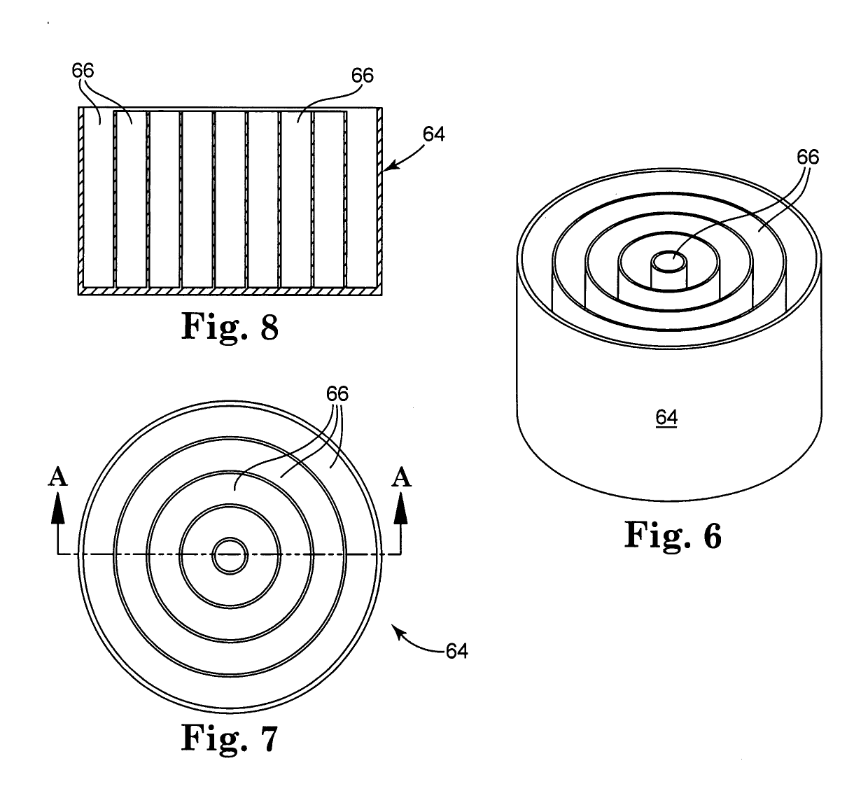

FIG. 6 shows another exemplary crucible 64 in accordance with the present invention that comprises concentric channels that provide plural distinct cells 66 for holding deposition material. A top view and cross-sectional view are provided by FIGS. 7 and 8, respectively. Cells 66 are not required to be concentric channels as illustrated and can have any shape, number, and/or density. Also, the arrangement of cells 66 is not required to be symmetrical.

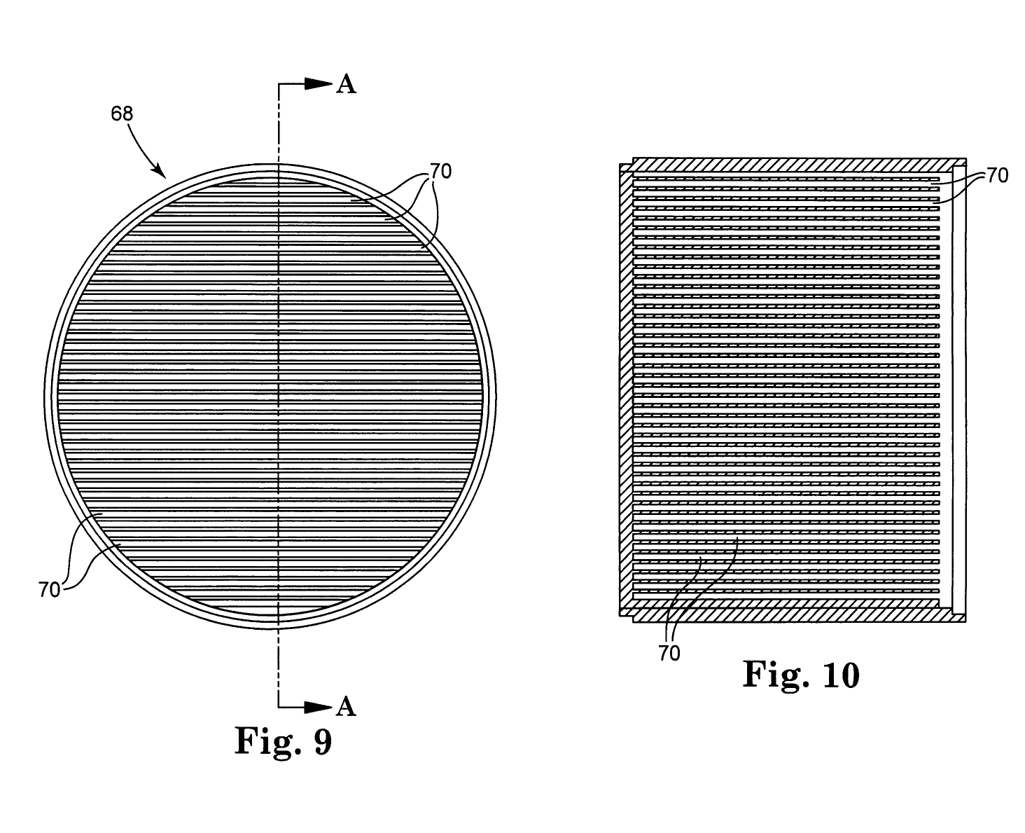

FIG. 9 shows another exemplary crucible 68 in accordance with the present invention that comprises parallel channels that provide plural distinct cells 70 for holding deposition material. A cross-sectional view is provided by FIG. 10. Cells 70 are not required to be parallel to each other as illustrated and can be provided at one or more angles relative to each other. Also, cells 70 are not required to be linear and may be arcuate, or serpentine, for example. Any shape, number, and/or density of cells 70 can be used in accordance with the present invention. Further, the arrangement of cells 70 is not required to be symmetrical.

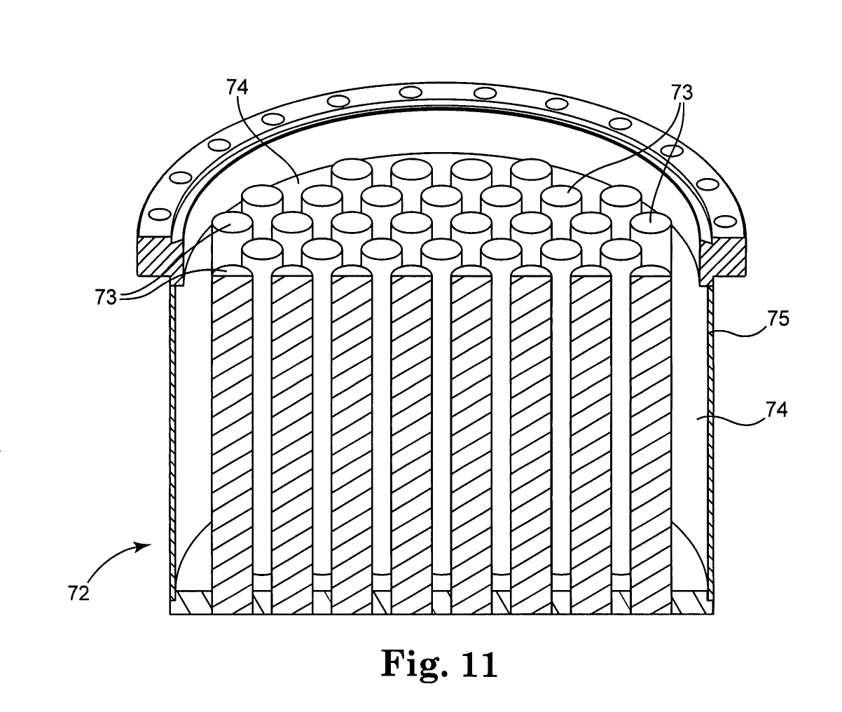

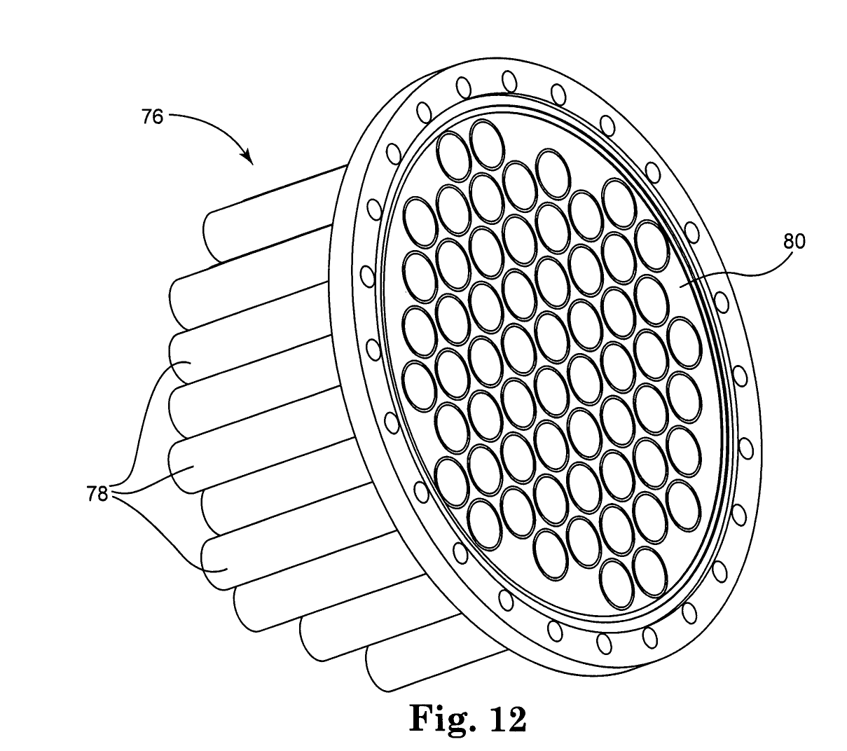

FIG. 11 shows another exemplary crucible 72 in accordance with the present invention. Crucible 72 comprises rods 73 that, together with wall 75, define cell 74 for holding deposition material. Rods 73 can comprise any desired shape, number, and/or density. A single rod may be used. The region between the outside surfaces of rods 73 and inside surface of crucible wall 75 is considered a single deposition material cell in accordance with the present invention. Also, the arrangement of rods 73 is not required to be symmetrical.

FIG. 17 shows another exemplary crucible 132 in accordance with the present invention. Crucible 132 is similar to crucible 72 of FIG. 11 and comprises rods 134 that, together with wall 136, define cell 138 for holding deposition material. Crucible 132 additionally includes heating devices 140 integrated with rods 134. Heating devices 140 can be controllable heated to provide thermal energy for vaporizing a deposition material provided in cell 138 of crucible 132.

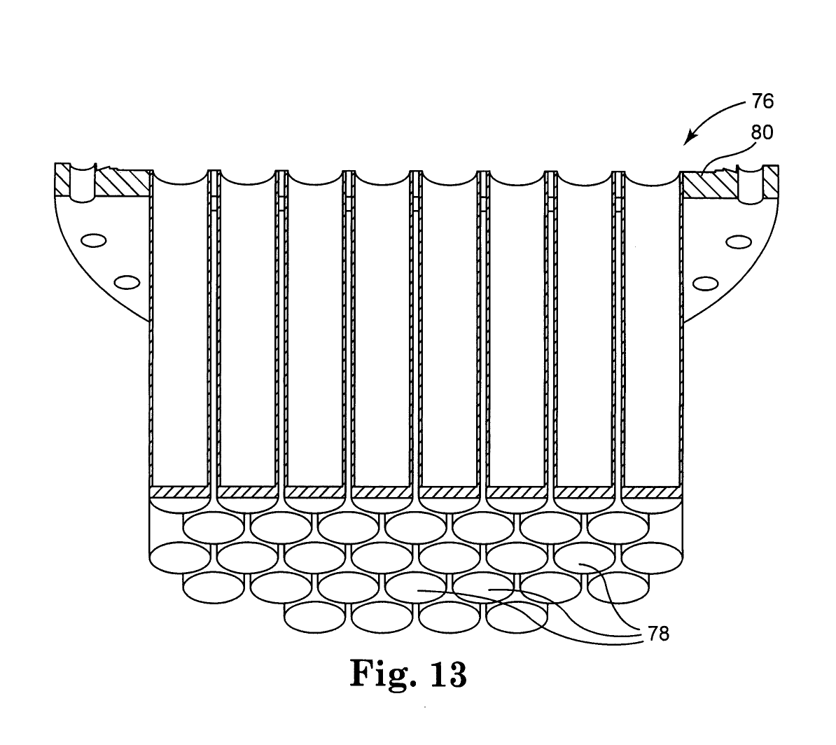

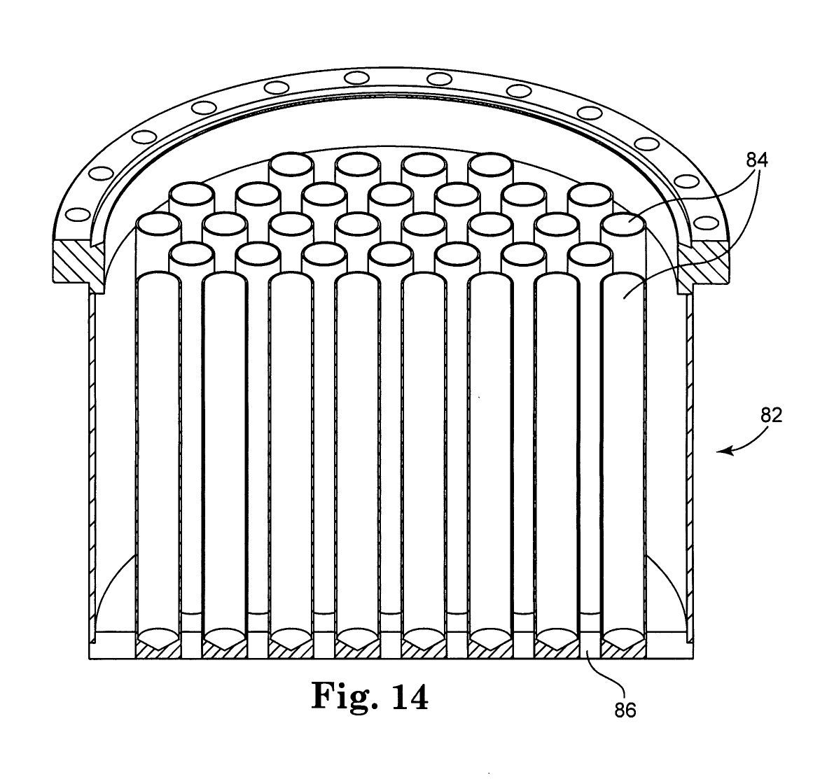

FIGS. 12 and 13 show exemplary crucible assembly 76 in accordance with the present invention that comprises an array of plural distinct crucibles 78 for holding deposition material wherein the crucibles are supported by a support plate 80 at the top (at the openings) of the crucibles. Crucibles 78 are not required to be parallel to each other as illustrated and can be provided at one or more angles relative to each other. Also, crucibles 78 are not required to be tubular in cross-section and may be square, rectangular, or elliptical in cross-section, for example. Any shape, number, and/or density of crucibles 78 can be used in accordance with the present invention. Further, the arrangement of crucibles 78 is not required to be symmetrical.

FIG. 14 shows another exemplary crucible assembly 82 in accordance with the present invention that comprises an array of plural distinct crucibles 84 for holding deposition material wherein the crucibles are supported by a support plate 86 at the bottom (at the bases) of the crucibles. Crucibles 84 can be supported by support plate 86 anywhere between the top and bottom of the crucibles. Crucibles 84 are not required to be parallel to each other as illustrated and can be provided at one or more angles relative to each other. Also, crucibles 84 are not required to be tubular in cross-section and may be square, rectangular, or elliptical in cross-section, for example. Any shape, number, and/or density of crucibles 84 can be used in accordance with the present invention. Further, the arrangement of crucibles 84 is not required to be symmetrical.

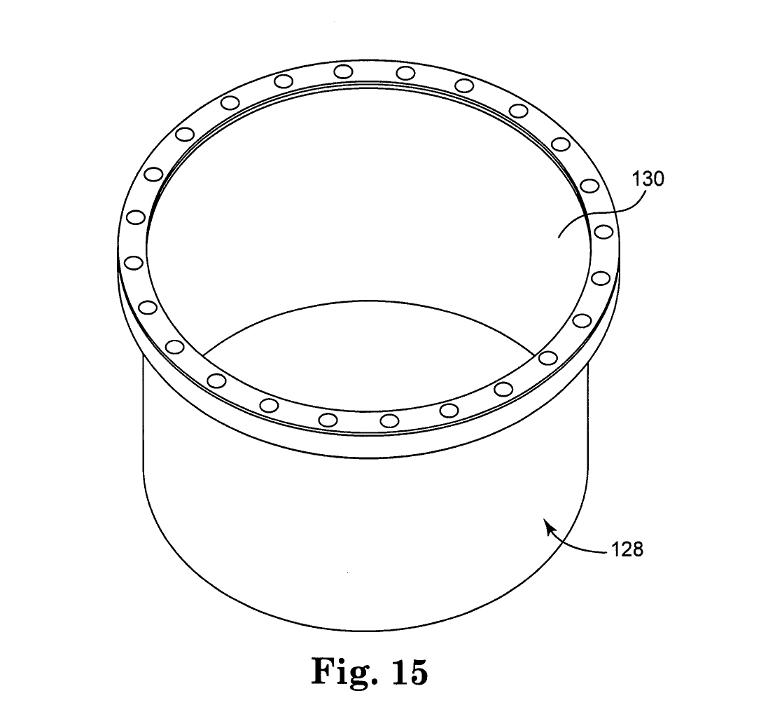

FIG. 15 shows another exemplary crucible assembly 118 in accordance with the present invention that comprises single cell 120 for holding deposition material and that can be used with deposition sources in accordance with the present invention.

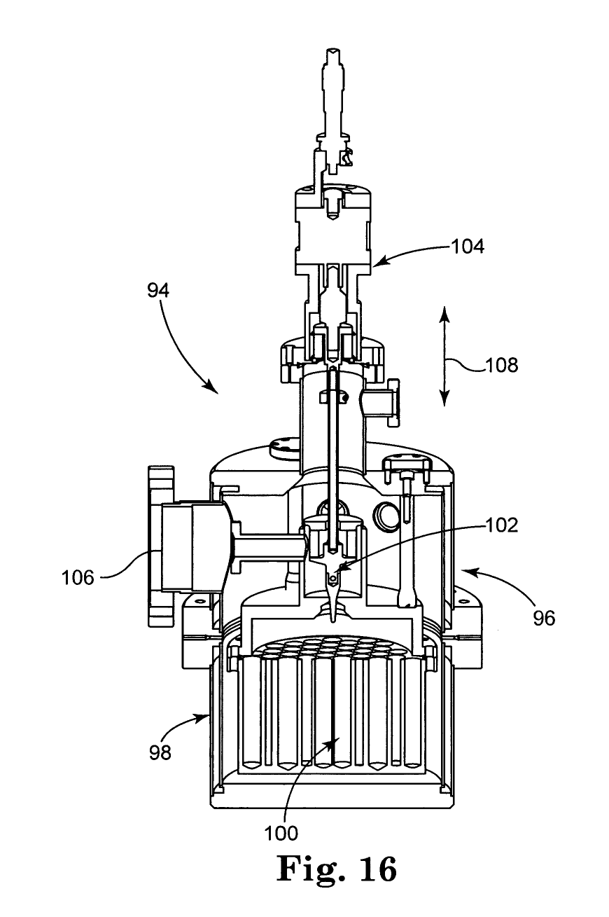

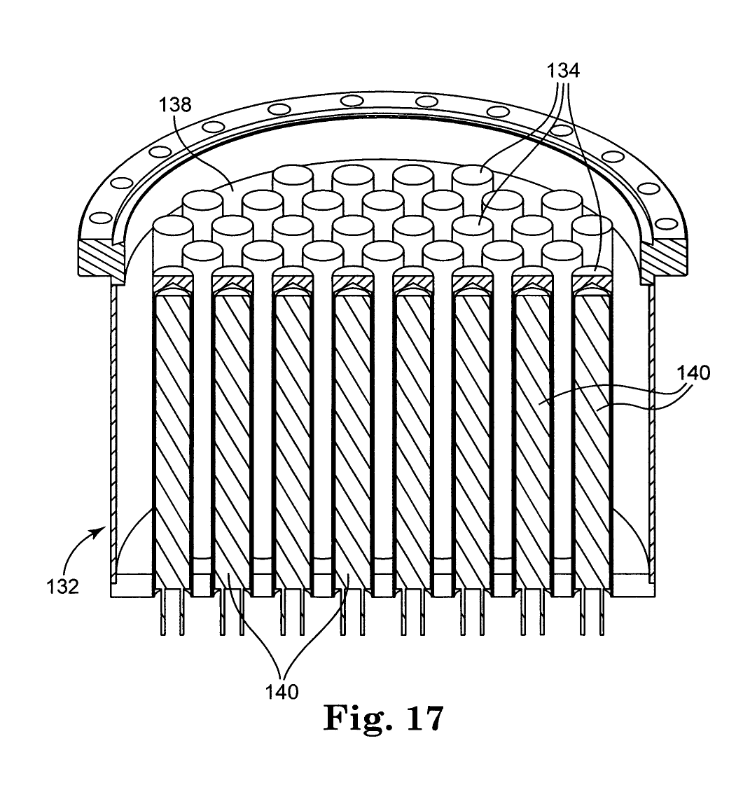

Another exemplary deposition source 94 in accordance with the present invention is illustrated in FIG. 16. Deposition source 94 includes first body portion 96, second body portion 98, crucible 100, valve 102, valve actuator 104, and nozzle port 106. Deposition source 94 is similar to deposition source 10 shown in FIGS. 1 and 2 but has a different valve orientation. That is, valve 102 comprises drive axis 108, which is oriented along the direction of material evaporation and/or sublimation from crucible 100. Any of the crucibles described herein may be used in deposition source 94.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

What is claimed is:

1. A vacuum deposition source, the vacuum deposition source comprising:
a body attachable to a vacuum deposition system, the body comprising first and second body portions separable from each other;
a valve positioned at least partially in the first body portion, the valve having an input side and an output side;
a crucible at least partially positioned in the second body portion and in communication with the input side of the valve, the crucible comprising a plurality of distinct deposition material cells; and
a nozzle comprising at least one exit orifice, the nozzle at least partially positioned in the first body portion and in communication with the output side of the valve.

2. The deposition source of claim 1, wherein the crucible comprises a heating device.

3. The deposition source of claim 1, wherein the nozzle comprises plural exit orifices.

4. The deposition source of claim 1, wherein the nozzle comprises a heating device.

5. The deposition source of claim 1 in combination with a vacuum deposition system.

6. A vacuum deposition source, the vacuum deposition source comprising:
a body attachable to a vacuum deposition system, the body comprising first and second body portions separable from each other;
a valve positioned at least partially in the first body portion, the valve having an input side and an output side;
a crucible at least partially positioned in the second body portion, detachably sealed to the input side of the valve, and isolated from the second body portion, the crucible comprising at least one deposition material cell; and
a nozzle comprising at least one exit orifice, the nozzle at least partially positioned in the first body portion and in communication with the output side of the valve.

7. The deposition source of claim 6, wherein the at least one deposition material cell of the crucible is at least partially defined by a plural rods.

8. The deposition source of claim 7, wherein the crucible comprises a heating device.

9. The deposition source of claim 6 in combination with a vacuum deposition system.

10. A vacuum deposition system, the vacuum deposition system comprising:
a vacuum chamber;
a vacuum deposition source attached to the vacuum chamber, the vacuum deposition source comprising first and second body portions separable from each other, a valve positioned at least partially in the first body portion, the valve having an input side and an output side, a crucible at least partially positioned in the second body portion and in communication with the input side of the valve, the crucible comprising a plurality of distinct deposition material cells, and a nozzle comprising at least one exit orifice, the nozzle at least partially positioned in the first body portion and in communication with the output side of the valve;
a deposition material provided in one or more of the plurality of deposition material cells of the crucible; and
a substrate positioned in the vacuum chamber and relative to the nozzle of the vacuum deposition source.

11. The vacuum deposition system of claim 10, wherein the deposition material comprises one or more of a granular, flake, or powder consistency.

12. The vacuum deposition system of claim 10, wherein the deposition material comprises one or more inorganic components.

13. The vacuum deposition system of claim 12, wherein the deposition material comprises Aluminum Tris (8-Hydroxyquinoline).

14. The vacuum deposition system of claim 10, wherein the substrate comprises at least a portion of an organic light-emitting device.

15. A crucible for a deposition source, the crucible comprising:
a body portion;
a flange capable of providing a seal with a gasket when the flange is attached to a similar flange; and
a plurality of distinct cells for holding deposition material.

16. The crucible of claim 15, wherein the crucible comprises one of titanium, stainless steel, and a nickel based alloy.

17. The crucible of claim 15, wherein the plurality of distinct deposition material cells comprise arcuate channels.

18. The crucible of claim 15, wherein the plurality of distinct deposition material cells comprise parallel channels.

19. The crucible of claim 15, wherein the plurality of distinct deposition material cells comprise tubes supported by a plate at an opening of the tubes.

20. The crucible of claim 15, wherein the plurality of distinct deposition material cells comprise tubes supported by a plate at a base of the tubes.

21. The crucible of claim 15, further comprising a heating device.

22. The crucible of claim 15 in combination with a vacuum deposition source.

23. A method of vaporizing material for vacuum deposition, the method comprising the steps of:
providing a crucible comprising a plurality of distinct deposition material cells;
positioning deposition material in at least one of the plurality of deposition material cells of the crucible; and
heating the crucible to vaporize the deposition material.

24. The method of claim 23, further comprising directing the vaporized deposition material with a nozzle.

25. The method of claim 24, comprising heating at least a portion of the nozzle.

26. The method of claim 23, comprising regulating the flow of deposition material with a valve.

27. The method of claim 26, comprising maintaining a higher pressure on an input side of the valve relative to an output side of the valve.

28. The method of claim 23, wherein the deposition material comprises one or more of a granular, flake, or powder consistency.

29. The method of claim 23, wherein the deposition material comprises one or more inorganic components.

30. The method of claim 23, wherein the deposition material comprises Aluminum Tris (8-Hydroxyquinoline).

31. A method of vaporizing material for vacuum deposition, the method comprising the steps of:
providing a crucible comprising at least one deposition material cell at least partially defined by a plural rods;
positioning deposition material in at least one deposition material cell of the crucible; and
heating the crucible to vaporize the deposition material.

32. The method of claim 31, wherein the step of heating the crucible comprises heating at least one of the plural rods with a heating device.
